(19) United States
(12) Patent Application Publication
(10) Pub. No.: US 2007/0031982 A1
(43) Pub. Date: Feb. 8, 2007

(54) Method of classifying defects and apparatus for performing the method

(76) Inventors: Young-Kyu Lim, Gyeonggi-do (KR); Byung-Am Lee, Gyeonggi-do (KR); Jae-Kyun Ko, Gyeonggi-do (KR); Song-Sik Lim, Gyeonggi-do (KR); Young-Woo Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/462,305

(22) Filed: Aug. 3, 2006

(30) Foreign Application Priority Data
Aug. 4, 2005 (KR) 2005-71227

(51) Int. Cl. H01L 21/66; G01N 21/00

(52) U.S. Cl. 438/14; 438/16; 356/237.1

(57) ABSTRACT

In a method of classifying defects, actual information with respect to actual defects by each of processes on an object on which the processes are sequentially carried out is obtained. The actual information is accumulated in sequence of the processes to obtain composite information by each of the processes with respect to entire defects that are generated in preceding processes. Added information with respect to defects, which are generated only in each of the processes, among the actual defects is obtained by each of the processes based on the actual information and the composite information. The added information contains information with respect to the defects generated only in each of the processes so that the detected defects may be accurately classified as defects generated in any one among the processes based on the added information.

### CROSS REFERENCE TO RELATED APPLICATION

This application claims priority under 35 U.S.C. § 119 to Korean Patent Application No. 2005-71227, filed on Aug. 4, 2005, the contents of which are herein incorporated by reference in their entirety for all purposes.

### BACKGROUND OF THE INVENTION

1. Field of the Invention

The present invention relates to a method of classifying defects and an apparatus for performing the method. More particularly, the present invention relates to a method and apparatus for classifying defects formed on a semiconductor substrate during processing steps, with the goal of assisting one in recognizing the particular process step that may have created the defects.

2. Description of the Related Art

Semiconductor processing is conducted in highly controlled environments such as clean rooms in order to reduce the chance of contamination, and thus possible failure, of the semiconductor device. Possible contamination sources include particles in air, contaminants generated from process equipment, reactants and/or products, etc. As semiconductor devices undergo hundreds of process steps during manufacture, it is often very difficult to maintain a contaminant-free surface of a wafer.

This problem is exacerbated by a continued decrease in size of the semiconductor devices. The statistical relation between the yield obtained during semiconductor manufacturing and the critical defect size capable of contaminating the device is represented by a following equation.
Y=Exp(−DA)

In the above equation, Y represents the yield, D indicates a density of the particle, and A represents an area of a circuit region in a semiconductor device. As shown in the equation, the yield Y is decreased in proportional to an increase of numbers DA of the particle on one semiconductor chip.

The critical defect size of particles has decreased over time as semiconductor processing becomes more advanced and circuit sizes are reduced. For instance, while it was necessary many years ago to remove contaminant particles 3 μm or more in size for 4M DRAM, more modern memory of 256M in size would require removal of particles 0.1 μm in size. Thus, a defect caused by a particle is increased in proportional to a decrease of a size of the particle that is to be removed. The yield of the devices during manufacture is severely reduced in a process for manufacturing a semiconductor device having a minute design rule. Therefore, it is extremely important to strictly manage the particles in order to obtain a high yield in a process for manufacturing semiconductor devices such as a 64M DRAM or the 256M DRAM.

Contaminant detection is typically classified into the steps of detecting the particle in the first place, and determining where the particle came from. A tool used during the manufacturing process that itself has become contaminated can transfer these contaminants to the semiconductor substrate. Accordingly, it is imperative that the contaminating process be identified so that the problematic step or tool is cleaned and/or fixed.

Methods for detecting and classifying particles had in the past used lamps which were characterized as adequate for large particle detection but inaccurate for small particle detection. As particle sizes decreased, however, inspection methods began using lasers.

In order to find the defect-generating process, several methods have been proposed. One such method for analyzing a defect map is disclosed in Japanese Patent Laid-Open Publication No. 1997-134940 where a defect inspection and a pattern inspection are carried out in each of processes to prepare defect maps. A second defect map that is prepared after performing a subsequent process is compared with a first defect map that is prepared after performing a preceding process. Newly detected defects on the second defect map are recognized as defects generated in the subsequent process.

In a method disclosed in Korean Patent Laid-Open Publication No. 2003-055848, a first process is carried out on semiconductor substrates. Any one among the semiconductor substrates is sampled. A first defect inspection is performed on the sample semiconductor substrate to obtain first inspection results. The first inspection results are stored in a first defect file. A second process is then carried out on the sampled semiconductor substrate. A second defect inspection is performed on the sample semiconductor substrate to obtain second inspection results. The second inspection results are stored in a second defect file. The first and second defect files are compared with each other to obtain non-repetitive defects. The non-repetitive defects are recognized as defects that are generated in the second process.

Finally, in a method disclosed in U.S. Pat. No. 6,794,203, defects are recognized from sensitivities of defects as well as a difference between numbers of the defects in preceding and subsequent processes.

Each of the above-mentioned conventional methods is only available for classifying defects that are generated in two processes serially performed. This limitation can lead to inaccuracies in the particle classification. For example, there are particles generated in a first process. The particles are found in a first inspection that is carried out after the first process. However, the particles are found in a third inspection that is carried out after a third process, but not found in a second inspection that is carried out after a second process. Since the conventional methods are only available for classifying defects generated in two serially performed processes, the particles are recognized as defects generated in the second process when the conventional methods are employed.

Further, for example, when a first process corresponds to a first deposition process for forming a first layer, a second process corresponds to a second deposition process for forming a second layer on the first layer, and a third process corresponds to an etching process for patterning the first and second layers, particles found after performing the etching process are not classified as defects generated in the first process or the second process using the conventional methods.

Furthermore, since a cleaning process for removing particles is necessarily carried out between processes for manufacturing a semiconductor device, it is very difficult to recognize any one of a preceding process and a subsequent process in which particles are found in an inspection that is carried out after performing the subsequent process.

Because defects accumulate in the many processes carried out during semiconductor processing, conventional methods do not allow one to identify a particular process step from which defects/contaminants result. As a result, immediate management is not performed with respect to a process in which many particles are generated.

Accordingly, the need remains for methods and systems that allow such process-specific identification and early intervention.

### SUMMARY OF THE INVENTION

The present invention provides a method of classifying defects that is capable of accurately recognizing a process in which the defects are generated.

The present invention also provides an apparatus for performing the above-mentioned method.

In a method of classifying defects in accordance with one aspect of the present invention, actual information with respect to actual defects by each of processes on an object on which the processes are sequentially carried out is obtained. The actual information is accumulated in sequence of the processes to obtain composite information by each of the processes with respect to entire defects that are generated in preceding processes. Added information with respect to defects, which are generated in only each of the processes, among the actual defects by each of the processes is obtained based on the actual information and the composite information.

In a method of classifying defects in accordance with another aspect of the present invention, first actual information with respect to first actual defects on a substrate on which a first process is carried out is obtained. The first actual information is set as first composite information. Second actual information with respect to second actual defects on the substrate on which a second process is carried out is obtained. The second actual information is compared with the first composite information to obtain added information with respect to defects that are generated in only the second process.

An apparatus for classifying defects in accordance with still another aspect of the present invention includes a defect-detecting unit for detecting defects on an object on which processes are sequentially carried out to obtain actual information with respect to actual defects by each of processes. An information-processing unit accumulates the actual information in sequence of the processes to obtain composite information by each of the processes with respect to entire defects that are generated in preceding processes. Further, the information-processing unit processes the actual information and the composite information to obtain added information with respect to defects, which are generated in only each of the processes, among the actual defects by each of the processes.

According to the present invention, the added information contains information with respect to the defects generated in only each of the processes so that the detected defects may be accurately classified as defects generated in any one among the processes based on the added information. Thus, a process in which numerous particles are generated is precisely recognized so that an immediate management may be performed on the process.

### BRIEF DESCRIPTION OF THE DRAWINGS

The above and other features and advantages of the invention will become readily apparent by reference to the following detailed description when considered in conjunction with the accompanying drawings wherein:

FIG. 1 is a block diagram illustrating an apparatus for classifying defects in accordance with one example embodiment of the present invention;

FIG. 2 is a flow chart illustrating a method of classifying defects using the apparatus in FIG. 1;

FIG. 3 is a substrate map illustrating first actual information;

FIG. 4 is a substrate map illustrating first composite information corresponding to the first actual information in FIG. 3;

FIG. 5 is a substrate map illustrating second actual information;

FIG. 6 is a substrate map illustrating first added information obtained from the first composite information and the second actual information;

FIG. 7 is a substrate map illustrating second composite information obtained from the first composite information and the second actual information;

FIG. 8 is a substrate map illustrating third actual information;

FIG. 9 is a substrate map illustrating second added information obtained from the second composite information and the third actual information;

FIG. 10 is a graph illustrating numbers of particles generated in each of processes obtained using the method in FIG. 2; and

FIG. 11 is a graph illustrating actual information and added information obtained using the method in FIG. 2.

### DESCRIPTION OF THE EMBODIMENTS

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or -layers present. Like numbers refer to like elements throughout. As used herein, the term “and/or” includes any and all combinations of one or-more of the associated-listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship-to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or-at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Apparatus for Classifying Defects

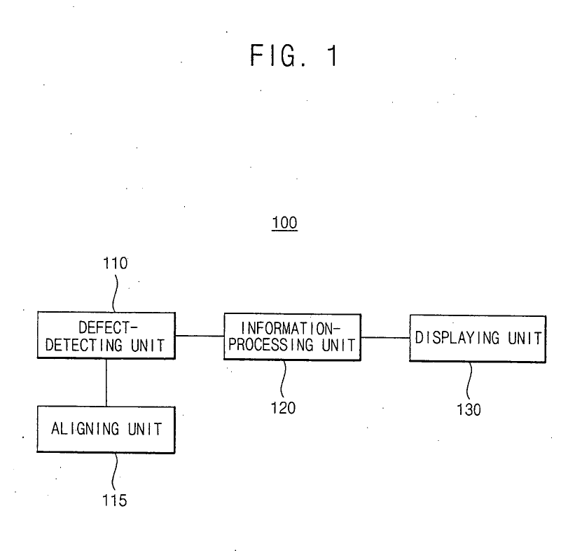

FIG. 1 is a block diagram illustrating an apparatus for classifying defects in accordance with one example embodiment of the present invention.

Referring to FIG. 1, an apparatus 100 for classifying defects of this example embodiment includes a defect-detecting unit 110 for detecting defects on a semiconductor substrate, an information-processing unit 120 for processing information with respect to the defects detected by the defect-detecting unit 110, and a displaying unit 130 for displaying the information processed by the information-processing unit 120.

The defect-detecting unit 110 detects the defects such as numbers and coordinates of particles on the semiconductor substrate on which any one among semiconductor-manufacturing processes is carried out. The defect-detecting unit 110 creates actual information with respect to the detected particles. Alternatively, the defect-detecting unit 110 may create the actual information with the detected defects based on a light reflected from the semiconductor substrate or an image obtained from the semiconductor substrate.

Further, the defect-detecting unit 110 includes an aligning unit 115 for aligning a reference point of the semiconductor substrate. Here, since the semiconductor-manufacturing processes include various processes such as a deposition process, an etching process, etc., that are carried out under conditions different from each other, defect-detecting equipments are different from each other. Although only single defect-detecting equipment is used for detecting the defects generated in the entire semiconductor-manufacturing processes, inspection conditions such as the condition for setting a reference point in the single defect-detecting equipment may be different from each other. When a defect-detecting process is carried out under the above-mentioned conditions, there is a problem that a particle positioned on a substantially same coordinate may be classified as a particle generated in a subsequent process. To prevent the above-mentioned problem, the aligning unit 115 corrects a reference point on the semiconductor substrate set in subsequent defect-detecting equipment to align the reference point set in the subsequent defect-detecting equipment with a reference point on the semiconductor substrate set in initial defect-detecting equipment.

The information-processing unit 120 accumulates the actual information created from the defect-detecting unit 110 in sequence of the semiconductor-manufacturing processes to create composite information by each of the processes with respect to entire defects that are generated in preceding processes. For example, the information-processing unit 120 continuously adds up the actual information accumulated from an initial process to the preceding process. That is, the information-processing unit 120 adds up the composite information for the preceding process to actual information created from a pre sent process to create composite information for the present process. Particularly, the actual information sequentially accumulated by the information-processing unit 120 corresponds to the composite information by each of the processes with respect to the defects generated in the preceding processes.

Further, the information-processing unit 120 compares the composite information for the preceding process with the actual information for the present process to create added information with respect to defects generated only in the present process. The added information corresponds to information with respect to the defects, that is, the numbers and the coordinates of the particles generated only in the present process. For example, a value subtracted the number of particles accumulated from the initial process to the preceding process from the number of particles detected in the present process corresponds to the number of particles generated only in the present process.

The displaying unit 130 displays positions of the actual information created by the defect-detecting unit 110, and the composite information and the added information created by the information-processing unit 120 on a substrate map. Further, the displaying unit 130 comparatively displays the composite information and the added information by each of the processes to immediately recognize any one among the semiconductor-manufacturing processes in which the numbers of the particles are rapidly increased.

Method of Classifying Defects

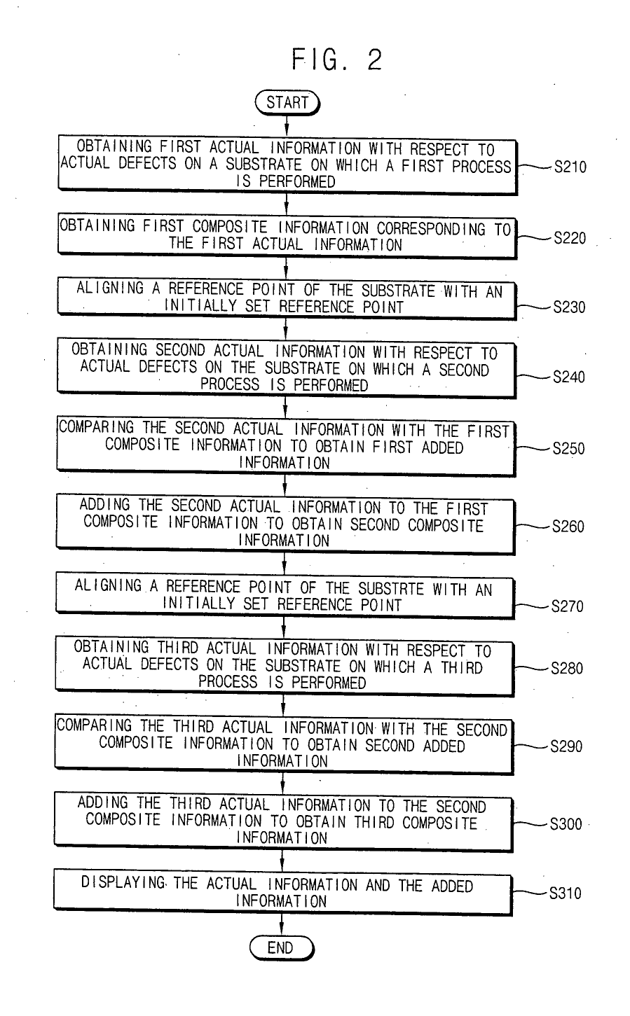

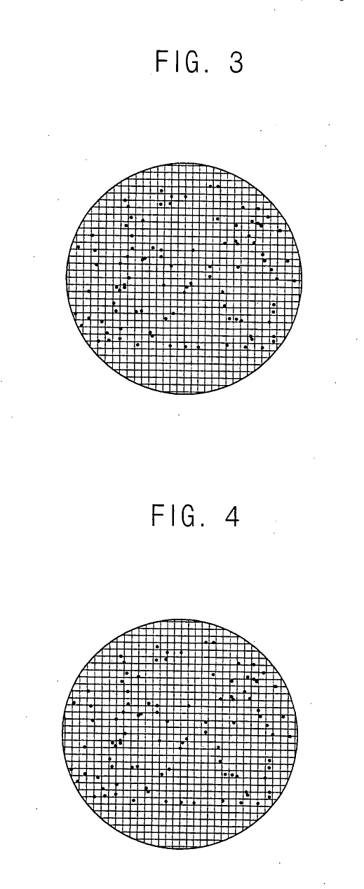

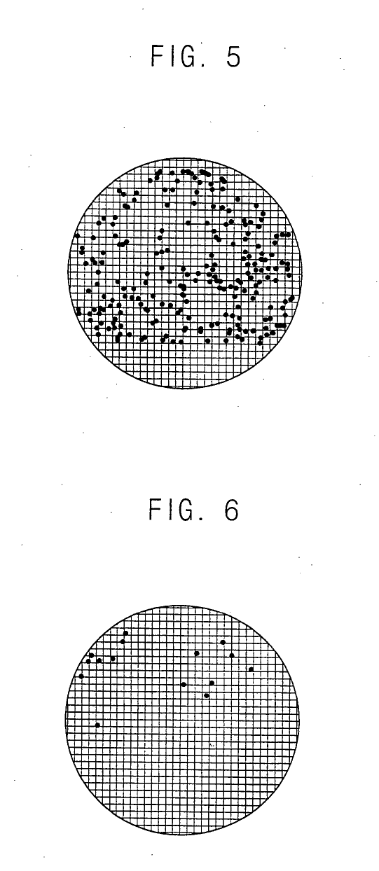

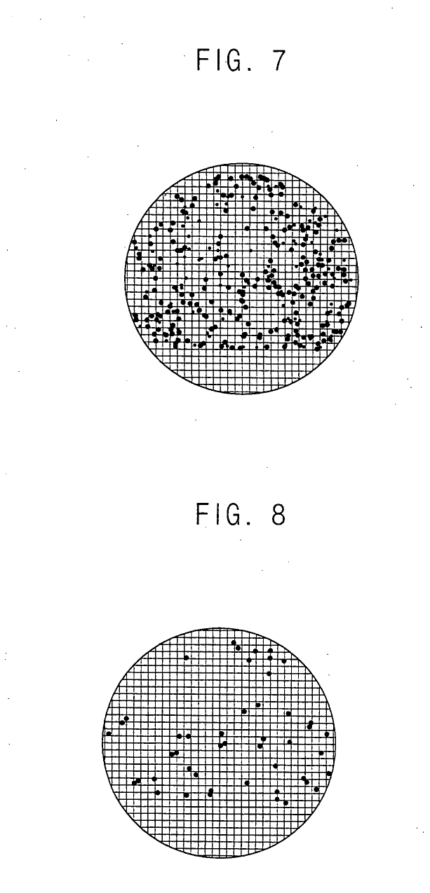

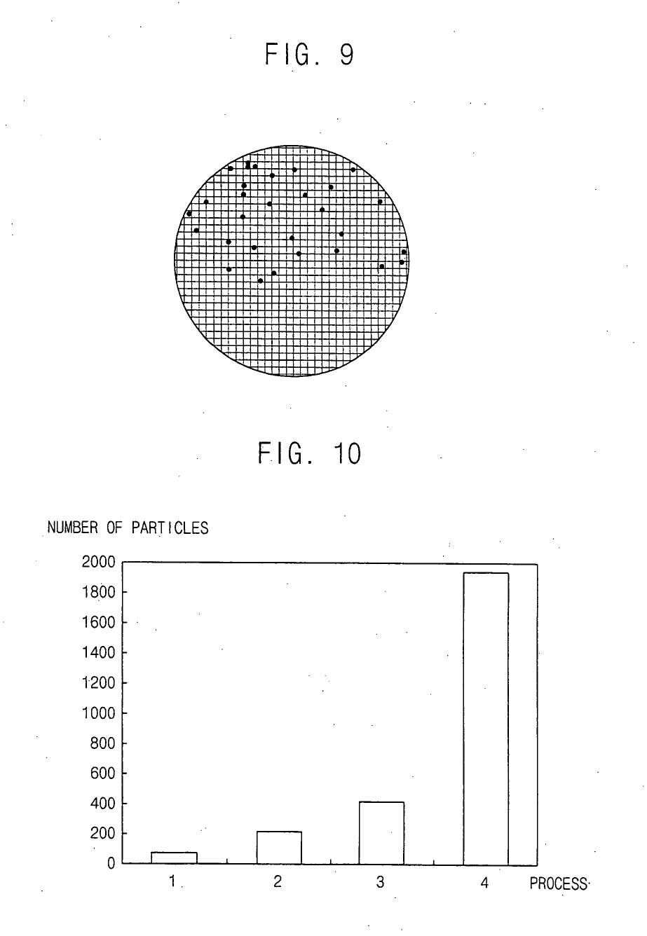

FIG. 2 is a flow chart illustrating a method of classifying defects using the apparatus in FIG. 1, FIG. 3 is a substrate map illustrating first actual information, FIG. 4 is a substrate map illustrating first composite information corresponding to the first actual information in FIG. 3, FIG. 5 is a substrate map illustrating second actual information, FIG. 6 is a substrate map illustrating first added information obtained from the first composite information and the second actual information, FIG. 7 is a substrate map illustrating second composite information obtained from the first composite information and the second actual information, FIG. 8 is a substrate map illustrating third actual information, and FIG. 9 is a substrate map illustrating second added information obtained from the second composite information and the third actual information.

Referring to FIG. 2, in step S210, the defect-detecting unit 110 detects actual defects such as particles on a semiconductor substrate on which a first process is carried out to create first actual information with respect to the actual defects. Here, the first actual information corresponds to the numbers and positions of the particles. The displaying unit 130 prepares a substrate map in FIG. 3 on which the positions of the defects are displayed, based on the first actual information provided from the defect-detecting unit 110.

In step S220, the information-processing unit 120 creates first composite information based on the first actual information. Here, since the first process corresponds to an initial process for manufacturing a semiconductor device, the first composite information is substantially same as the first actual information. Accordingly, the displaying unit 130 prepares a substrate map in FIG. 4 that is substantially the same as that in FIG. 3.

In step S230, the aligning unit 115 aligns a reference point of the semiconductor substrate. That is, the aligning unit 115 corrects the reference point of the semiconductor substrate to align the reference point with an initially set reference point.

In step S240, a second process is then carried out on the semiconductor substrate. The defect-detecting unit 110 detects actual defects on the semiconductor substrate to create second actual information with respect to the actual defects on the semiconductor substrate on which the second process is performed. The displaying unit 130 prepares a substrate map in FIG. 5 on which the positions of the defects are displayed, based on the second actual information provided from the defect-detecting unit 110.

In step S250, the information-processing unit 120 compares the second actual information with the first composite information to create first added information. The first added information corresponds to information defects that are included only in the second actual information, but not included in the first composite information. Thus, the first added information includes numbers and positions of particles generated only in the second process. The displaying unit 130 prepares a substrate map in FIG. 6 on which the positions of the defects generated in only the second process are displayed, based on the first added information.

In step S260, the information-processing unit 120 adds the first composite information to the second actual information to create second composite information. The displaying unit 130 prepares a substrate map in FIG. 7 on which the positions of the defects generated in the first and second processes are displayed, based on the second composite information.

Here, when a cleaning process for removing the particles generated in the first process is not carried out between the first and second processes, the defects generated in the first and second processes may be wholly displayed on the substrate map in FIG. 7. Thus, the second composite information (FIG. 7) is substantially the same as the second actual information (FIG. 8). Alternately, when a cleaning process is performed between the first and second processes or the second process corresponds to an etching process, the number of particles detected after performing the second process may be fewer than the number of particles detected after performing the first process. Thus, the numbers of the particles on the substrate map in FIG. 5 would be fewer than those of the particles on the substrate map in FIG. 3. Further, the number of the particles on the substrate map in FIG. 7 corresponds to a sum of the number of particles on the substrate map in FIG. 4 and the number of particles on the substrate map in FIG. 5. As a result, the second composite information includes the defects generated in the first and second processes.

In step S270, the aligning unit 115 again aligns a reference point of the semiconductor substrate with the initially set reference point.

In step S280, a third process is then carried out on the semiconductor substrate. The defect-detecting unit 110 detects actual defects on the semiconductor substrate to create third actual information with respect to the actual defects on the semiconductor substrate on which the third process is performed. The displaying unit 130 prepares a substrate map in FIG. 8 on which the positions of the defects are displayed, based on the third actual information.

In step S290, the information-processing unit 120 compares the third actual information with the second composite information to create second added information. The second added information corresponds to information defects that are included only in the third actual information, but not included in the second composite information. Thus, the second added information includes numbers and positions of particles generated in only the third process. The displaying unit 130 prepares a substrate map in FIG. 9 on which the positions of the defects generated only in the third process are displayed, based on the second added information.

In step S300, the information-processing unit 120 adds the second composite information to the third actual information to create third composite information. The third composite information includes the defects generated in the first, second and third processes.

After subsequent processes next to the second process are carried out, actual information, composite information and added information are obtained using the above-mentioned method. The composite information includes information with respect to defects generated in preceding processes before the present process is conducted. The added information includes information with respect to defects generated in each of processes.

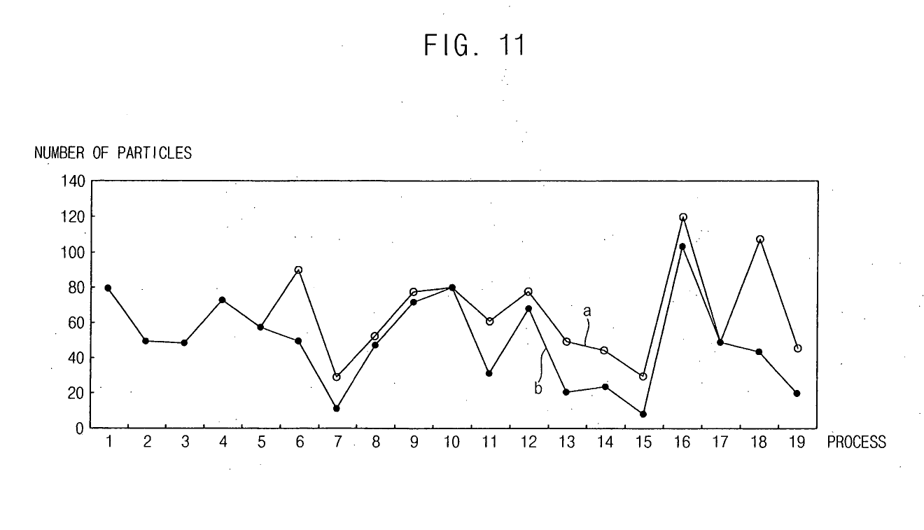

In step S310, the displaying unit 130 displays the numbers of the particles generated in each of the processes based on the added information by each of the processes as a histogram in FIG. 10. Therefore, an inspector immediately recognizes any one among the semiconductor-manufacturing processes in which numerous particles are generated based on the results on the FIG. 10. Thus, treatment such as repair, exchange, etc., with respect to the corresponding process may be immediately performed.

Further, the displaying unit 130 comparatively displays the actual information and the added information by each of the processes, as shown in FIG. 11. In FIG. 11, line a represents the numbers of the particles based on the actual information, and line b represents the numbers of the particles based on the added information. A difference between the lines a and b corresponds to the numbers of the actual particles that are generated in each of the semiconductor-manufacturing processing steps.

According to the present invention, the added information contains information with respect to the defects generated only in each of the processes so that the detected defects may be accurately classified as defects generated in any one among the processes based on the added information. Further, a process in which relatively numerous particles are generated is precisely recognized. Thus, an immediate management may be performed on the process so that semiconductor-manufacturing efficiency may be improved.

Having described the preferred embodiments of the present invention, it is noted that modifications and variations can be made by persons skilled in the art in light of the above teachings. It is therefore to be understood that changes may be made in the particular embodiment of the present invention disclosed which is within the scope and the spirit of the invention outlined by the appended claims.

What is claimed is:

1. A method of classifying defects on an object undergoing a sequence of processing steps, the method comprising:
obtaining actual information with respect to actual defects resulting from each of the processing steps carried out on the object;
accumulating the actual information of preceding processing steps within the sequence to obtain composite information with respect to accumulated defects generated in the preceding processing steps; and
obtaining added information with respect to defects generated in each of the processing steps based on the actual information and the composite information.

2. The method of claim 1, wherein obtaining the actual information comprises aligning a reference point of the object with an initially set reference point.

3. The method of claim 1, wherein accumulating the actual information of preceding processing steps within the sequence to obtain the composite information comprises:
setting first actual information with respect to first actual defects on the object on which a first process among the processes is carried out as first composite information; and
adding the first composite information to second actual information with respect to second actual defects on the object on which a second process is carried out to obtain second composite information.

4. The method of claim 1, wherein obtaining the added information comprises:
comparing the composite information with the actual information; and
setting information included only in the actual information, but not included in the composite information as the added information.

5. The method of claim 1, wherein the actual information, the composite information and the added information comprise the number of the defects.

6. The method of claim 1, wherein the actual information, the composite information and the added information comprise coordinates of the defects.

7. The method of claim 1, further comprising comparatively displaying the actual information and the added information by each of the processes.

8. The method of claim 1, wherein the object comprises a semiconductor substrate.

9. The method of claim 8, wherein the defects comprise particles on the semiconductor substrate.

10. A method of classifying defects on a semiconductor substrate, comprising:
obtaining first actual information with respect to first actual defects on the semiconductor substrate on which a first process is carried out;
setting the first actual information as first composite information;
obtaining second actual information with respect to second actual defects on the semiconductor substrate on which a second process is carried out; and
comparing the second actual information with the first composite information to obtain added information with respect to defects generated only in the second process.

11. The method of claim 10, wherein obtaining the first actual information and the second actual information comprises aligning a reference point of the semiconductor substrate with an initially set reference point.

12. The method of claim 10, further comprising adding the second actual information to the first composite information to obtain second composite information with respect to accumulated defects generated in the first and second processes.

13. The method of claim 10, further comprising comparatively displaying the first and second actual information and the added information by each of the processes.

14. The method of claim 10, wherein the defects comprise particles on the semiconductor substrate.

15. An apparatus for classifying defects on an object, comprising:
a defect-detecting unit for detecting the defects on the object on which processing steps are sequentially carried out to create actual information with respect to actual information resulting from each of the processing steps; and
an information-processing unit for accumulating the actual information in sequence of the processing steps to create composite information by each of the processing steps with respect to accumulated defects generated in preceding processes, and for creating added information defects, which are generated in each of the processing steps, among the actual defects by each of the processing steps based on the actual information and the composite information.

16. The apparatus of claim 15, wherein the defect-detecting unit comprises an aligning unit for aligning a reference point of the object with an initially set reference point.

17. The apparatus of claim 15, further comprising a displaying unit for comparatively displaying the actual information, the composite information and the added information.

18. The apparatus of claim 17, wherein the displaying unit prepares an object map on which the actual information, the composite information and the added information are displayed.
